(19) United States
(12) Patent Application Publication
(10) Pub. No.: US 2024/0224788 A1
(43) Pub. Date: Jul. 4, 2024

(54) LUMINESCENT GOLD (III) COMPOUNDS WITH THERMALLY ACTIVATED DELAYED FLUORESCENCE (TADF) AND THERMALLY STIMULATED DELAYED PHOSPHORESCENCE (TSDP) PROPERTIES FOR ORGANIC LIGHT-EMITTING DEVICES AND THEIR PREPARATION

(71) Applicant: THE UNIVERSITY OF HONG KONG, Hong Kong (CN)

(72) Inventors: Vivian Wing-Wah YAM, Hong Kong (CN); Ming-Yi LEUNG, Hong Kong (CN); Man-Chung TANG, Hong Kong (CN); Mei-Yee CHAN, Hong Kong (CN)

(21) Appl. No.: 18/551,504

(22) PCT Filed: Mar. 25, 2022
(86) PCT No.: PCT/CN2022/083067

§ 371 Date: Sep. 20, 2023

Related U.S. Application Data
(60) Provisional application No. 63/186,261, filed on May 10, 2021.

(51) Int. Cl. H10K 85/30; C07F 1/00; C09K 11/06; H10K 50/12

(52) U.S. Cl. CPC H10K 85/371; C07F 1/00; C09K 11/06; C09K 2211/1059; C09K 2211/188; H10K 50/12

(57) ABSTRACT

Described herein is a novel concept of the realization of thermally activated delayed fluorescence (TADF) and thermally stimulated delayed phosphorescence (TSDP) to harvest light emission from the higher-energy singlet and triplet excited states via the up-conversion from the lowest-energy triplet excited state by efficient reverse internal conversion together with reverse intersystem crossing as well as the development of emitters with TADF and TSDP properties, as exemplified by a new class of gold (III) compounds with TADF and TSDP properties. The gold (III) compounds include N-heterocycle-containing cyclometalating tridentate ligand and one auxiliary ligand, both coordinated to a gold (III) metal centre and having the chemical structure shown in generic formula (I).

This international patent application claims the benefit of U.S. Provisional Patent Application No. 63/186,261 filed on May 10, 2021, the entire content of which is incorporated by reference for all purpose.

### FIELD

Described herein is a novel class of luminescent small-molecular and dendritic gold (III) compounds with donor and acceptor units that has close-lying singlet and triplet excited states exhibiting thermally activated delayed fluorescence (TADF) and thermally stimulated delayed phosphorescence (TSDP), as well as the syntheses and uses of these compounds.

### BACKGROUND

Taking the advantages of low cost, light weight, low power consumption, high brightness, excellent color tunability, wide viewing angle of up to 180 degrees as well as their ease of fabrication onto flexible substrates, organic light-emitting devices (OLEDs) are considered as remarkably attractive candidates for flat panel display technologies and solid-state lighting systems. Typically, an OLED consists of several layers of semiconductors sandwiched between two electrodes. The cathode is composed of a low work function metal or metal alloy deposited by vacuum evaporation, whereas the anode is a transparent conductor such as indium tin oxide (ITO). Upon the application of a direct current (DC) voltage, holes injected from the ITO anode and electrons injected from the metal cathode will recombine to form excitons. Subsequent relaxation of excitons will then result in the generation of electroluminescence (EL).

The breakthroughs that led to the exponential growth of this field and to its first commercialized products can be traced to two pioneering demonstrations. In 1987, Tang and VanSlyke [Tang, C. W.; VanSlyke, S. A. Appl. Phys. Lett. 51, 913 (1987)] proposed the use of a double-layer structure of vacuum deposited, small-molecular films, in which tris(8-hydroxyquinoline) aluminum (Alq₃) was utilized both as light-emitting layer and electron-transporting layer. Later in 1998, Forrest and Thompson demonstrated the use of a transition metal complex, 2,3,7,8,12,13,17,18-octaethyl-21H,23H-porphine platinum(II) [Pt(OEP)] as emitter and fabricated a highly efficient phosphorescent OLED with external quantum efficiency (EQE) of ˜4% [Baldo, M. A.; O'Brien, D. F.; You, Y.; Shoustikov, A.; Sibley, S.; Thompson, M. E.; Forrest, S. R. Nature 395, 151 (1998)]. The introduction of a heavy metal center into the organic frameworks can effectively lead to a strong spin-orbit coupling and thus promotes an efficient intersystem crossing from the singlet excited state to the lower-energy triplet excited state to give phosphorescence. This can result in theoretically a four-fold enhancement in the internal quantum efficiency (IQE) of the OLEDs up to 100% upon the harvesting of both triplet and singlet excitons. An iridium(III)-phenylpyridine complex has also been used for the fabrication of phosphorescent OLEDs [Baldo, M. A.; Lamansky, S.; Burrows, P. E.; Thompson, M. E.; Forrest, S. R. Appl. Phys. Lett. 75, 4 (1999)]. High-performance triplet emitters based on metal complexes have been developed, and they are employed for the fabrication of highly efficient OLEDs; EQEs of up to 30% have been recently achieved.

Apart from the development of small-molecular materials, conjugated polymers are another promising class of emitters for OLEDs. In 1999, Friend and co-workers demonstrated the first polymer-based OLED with high efficiency by using conjugated polymer, poly (p-phenylene vinylene) (PPV) [Friend, R. H.; Gymer, R. W.; Holmes, A. B.; Burroughes, J. H.; Marks, R. N.; Taliani, C.; Bradley, D. D. C.; Dos Santos, D. A.; Brédas; Lögdlund, M.; Salaneck, W. R. Nature 397, 121 (1999)]. Conjugated polymers have conjugation of single and double bonds in their polymer backbone chain that makes them intrinsically conducting in nature. In addition, they are easily soluble in organic solvents and aqueous solution and can be easily adapted for printing and other solution-processing techniques. However, it is difficult to control the morphology of the emissive layers, specifically for large-area displays. Together with the large variation in the degree of polymerization and molar mass of polymers, it is hard to produce a high batch-to-batch reproducibility.

Dendrimers play the role of an intermediate between polymers and small molecules, possessing advantages of both. Dendrimers refer to branched macromolecules that are made up of repetitive units called dendrons and contain a well-defined size and number of peripheral groups. A dendrimer typically consists of three parts, namely a core unit, surrounding dendrons and peripheral groups. The branching levels of the surrounding dendrons is known as the dendrimer generation. Usually, the emissive chromophores are localized in the core of dendrimer, and the peripheral groups controls the intermolecular interactions, solubility, viscosity and processability of dendrimer. Typically, dendrimers are categorized into two major classes: conjugated dendrons and saturated dendrons. The branching point of conjugated dendrons or dendrimers must be fully conjugated but not necessarily delocalized [Burn, P. L.; Lo, S. C.; Samuel, I. D. W. Adv. Mater 19, 1675 (2007)]. The well-defined structure and precise molecular weight of dendrimers allow a precise control on the purity of the product. The high solubility also allows them to be employed in solution-processed devices, using techniques like spin-coating and ink jet printing, that are much more cost-effective and suitable for large-area printing when compared to the traditional vacuum deposition techniques. Another advantage of dendrimers in the application in OLEDs is the ability to control intermolecular interactions through the number of generations. With the introduction of bulky peripheral groups, intermolecular interactions can be suppressed, reducing the formation of dimers or excimers and therefore triplet-triplet annihilation. The high glass transition temperatures of these large molecules are also advantageous to device operational stability. The first dendrimer-based OLED was reported by Wang et al. [Wang P. W.; Liu, Y. J.; Devadoss, C.; Bharathi, P.; Moore, J. S. Adv. Mater 8, 237 (1996)]. The core used is 9,10-bis(phenylethynyl)-anthracene and the surrounding dendrons are comprised of phenylacetylene, with tertiary butyl groups as peripheral groups.

Remarkable discoveries on metal-free organic materials with thermally activated delayed fluorescence (TADF) properties have injected a new twist to the field of OLEDs. In theory, a rational design on the molecular structure to have a small energy gap between the lowest energy triplet (T₁) state and the lowest energy singlet (S₁) state can render up-conversion from the triplet state to the singlet state by reverse intersystem-crossing (RISC) possible. The newly generated singlet excitons can then decay through radiative process to give delayed fluorescence. With a small energy gap between the S₁ and T₁ states and high RISC rate constant, a 100% exciton utilization can be realized. Although the first report on TADF can be dated back to 1961, this type of materials was not applied on OLEDs. It was in 2009 that Adachi and co-workers realized TADF based OLEDs by the utilization of a Sn(IV)-porphyrin complex [Endo, A.; Ogasawara, M.; Takahashi, A.; Yokoyama, D.; Kato, Y.; Adachi, C. Adv. Mater. 21, 4802 (2009)]. The first purely organic TADF emitter in 2011 showed a 5.3% EQE in OLEDs, approaching the theoretical practical limit for singlet emitters [Endo, A.; Sato, K.; Yoshimura, K.; Kai, T.; Kawada, A.; Miyazaki, H.; Adachi, C. Appl. Phys. Lett. 98, 083302 (2011)]. In 2012, a series of ground-breaking organic TADF emitters were reported by the same group, in which an astonishing EQE of 19.3% was achieved in the best performing devices, well-beyond the theoretical practical maximum of 5% for singlet emitters [Uoyama, H.; Goushi, K.; Shizu, K.; Nomura, H.; Adachi, C. Nature 492, 234 (2012)]. Since then, TADF emitters have been one of the hottest topics in both academic and industrial research.

Nevertheless, TADF emitters still suffer from some major challenges. As both the population of T₁ from S₁ and the radiative decay process, i.e. delayed fluorescence, would rely on the respective spin-forbidden ISC and up-conversion via the spin-forbidden RISC to populate the higher-lying S₁ state, which are usually not very efficient without a strong spin-orbit coupling, especially with the lack of heavy metal centers in these systems, this would inevitably result in long-lived triplet states with lifetimes in hundreds of microseconds to milliseconds range, giving rise to rather long delayed fluorescence lifetimes of purely organic TADF systems. A long emission lifetime will lead to various undesirable excitonic processes, such as exciton-exciton annihilation, exciton-polaron annihilation etc. that will lead to reduced quantum efficiency and even decomposition of emitters. In 2017, our research group has pioneered a concept coined by us as “thermally stimulated delayed phosphorescence (TSDP)”. This TSDP mechanism is unique and unprecedented, which unlike TADF where the thermal up-conversion of excitons from lower-energy excited states to higher-energy excited states takes place via reverse intersystem crossing (RISC), the thermal up-conversion in TSDP occurs via reverse internal conversion (RIC) [U.S. patent application Ser. No. 16/959,462; Tang, M.-C.; Leung, M.-Y.; Lai, S.-L.; Ng, M.; Chan, M.-Y.; Yam V. W.-W. J. Am. Chem. Soc. 140, 13115 (2018)].

### SUMMARY

Instead of the up-conversion to the singlet state, the excitons in the TSDP compounds are found to be up-converted from the T₁ state to the second lowest energy triplet state T₁′ (T₁′ refers to a triplet state that has a different excited state origin from T₁; T₁′ will be equivalent to T₂ if it shares the same excited state origin as T₁. For simplicity, only T₁′ is used in the following context, which also covers the meaning of T₂) through efficient spin-allowed reverse internal conversion (RIC), resulting in phosphorescence with higher energy upon relaxation of the T₁′ state. With the incorporation of heavy metal center in the TSDP system, the large spin-orbit coupling constant would give rise to efficient ISC, thereby leading to a shorter triplet excited state lifetime relative to the pure organic system. In addition, the more efficient spin-allowed RIC for up-conversion is utilized instead of the spin-forbidden RISC, leading to a faster up-conversion process when compared to TADF. Overall, the emission lifetime can be shortened to the microsecond regime.

In one embodiment of the present disclosure, with both TADF and TSDP operating, three channels of radiative decay, namely prompt phosphorescence, TADF and TSDP are active, instead of only two channels in the TADF or TSDP alone systems, as shown in FIG. 1. In one embodiment, the extra channel in the present disclosure can increase the overall radiative decay rate constant (kᵣ) by providing multiple pathways for excitons to return to the ground state, giving rise to larger kᵣ, rendering the radiative decay process more competitive relative to the non-radiative decay to result in higher photoluminescence quantum yields as well as shorter-lived excited states. Thus, with TADF and TSDP mechanisms, enhanced radiative decay and luminescence from both S₁, T₁ and T₁′ excitons can be resulted, leading to fast radiative decay that can potentially shorten the excited state lifetime to sub-microsecond regime and improve the photoluminescence quantum yield of the complexes and the external quantum efficiency of the corresponding devices. Since both TADF and TSDP involve the up-conversion of excitons from lower energy states to higher energy states, in one embodiment, the present disclosure is useful for the design of blue-emitting materials, in which high-energy emissive states are required. Specifically, the development of blue-emitting phosphorescent materials is lagging behind as compared to their red- and green-emitting counterparts, particularly in the stability aspect. The low stability of blue emitters usually results in the degradation of OLED devices, causing deterioration of display colors. This is also true for the gold(III) system, in which the operational lifetimes of devices based on red- and green-emitting gold(III) complexes can reach up to 80,000 and 63,000 hours [Li, L.-K.; Tang, M.-C.; Lai, S.-L.; Ng, M.; Kwok, W.-K.; Chan, M.-Y.; Yam, V. W.-W. Nature Photon 13, 185 (2019)], while those of based on blue-emitting gold(III) complexes are less than 10 hours [Tang, M.-C.; Leung, M.-Y.; Lai, S.-L.; Ng, M.; Chan, M.-Y.; Yam V. W.-W. J. Am. Chem. Soc. 140, 13115 (2018)]. In one embodiment, the present disclosure definitely provides an alternative strategy towards the realization of stable blue emitters. This occurrence of TADF and TSDP properties for metal complexes has never been reported in the literature. Moreover, dendritic structure is introduced to improve the solubility of this class of complexes. In certain embodiments, particularly, with the highly branched peripheral groups, intermolecular interactions are effectively reduced in dendritic compounds, resulting in suppressed excimeric emission and improved solubility. Thus, in certain embodiments, a higher color purity can be achieved, especially for blue emitters. Meanwhile, taking the advantage of high solubility, thin films of these compounds can be prepared by various solution-processing techniques, such as spin-coating and ink jet printing, which are more cost-effective and suitable for large-area displays as compared to the traditional vacuum deposition technique for the fabrication of OLEDs. This present disclosure is anticipated to have important energy and environmental implications through the exploration of new classes of triplet emitters that are thermally evaporable and solution processable for the OLED display and solid-state lighting industries.

In one embodiment, a novel class of luminescent small-molecular and dendritic gold(III) compounds with donor and acceptor units that has close-lying singlet and triplet excited states exhibiting TADF and TSDP is provided. In another embodiment, the syntheses of these compounds and their characterization are provided.

The occurrence of TADF and TSDP properties is realized through the rational design of specific combinations of donor, acceptor, and pincer ligands to achieve a proximity of the energies of S₁, T₁ and T₁′ excited states, rendering all three channels of radiative decay through RISC, RIC, and prompt phosphorescence.

The novel luminescent small-molecular and dendritic gold(III) compounds are either saturated or conjugated dendrimers containing one strong o-donating group and a N-heterocycle-containing cyclometalating tridentate ligand, both coordinated to a gold(III) metal center.

In one or more embodiments, novel luminescent gold(III) compounds with TADF and TSDP properties having the chemical structure shown in the generic formula (I) are provided,

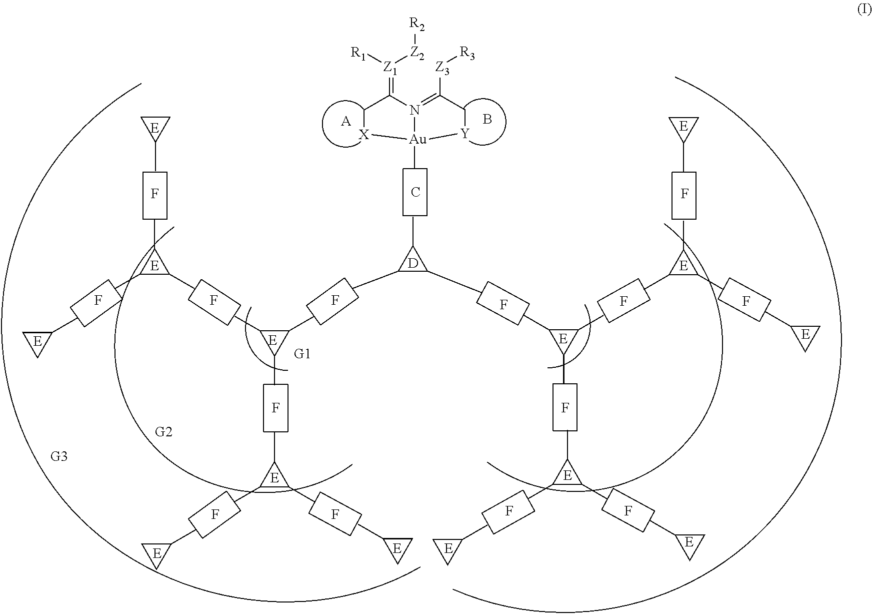

wherein:
(a) X, Y, Z₁, Z₂ and Z₃ are nitrogen or carbon;
(b) A and B are independently cyclic structure derivatives of unsubstituted or substituted phenyl groups or heterocyclic groups;
(c) When Z₁, Z₂ or Z₃ is carbon, R₁, R₂ and R₃ are independently selected from, but not limited to, hydrogen, alkyl, substituted alkyl, alkenyl, substituted alkenyl, alkynyl, substituted alkynyl, alkylaryl, substituted alkylaryl, aryl, substituted aryl, alkylalkenyl, substituted alkylalkenyl, arylalkenyl, substituted arylalkenyl, alkylalkynyl, substituted alkylalkynyl, arylalkynyl, substituted arylalkynyl, cycloalkyl, substituted cycloalkyl, cycloalkenyl, substituted cycloalkenyl, cycloalkynyl, substituted cycloalkynyl, heteroaryl, substituted heteroaryl, heterocyclic, substituted heterocyclic, heteroalkylalkynyl, substituted heteroalkylalkynyl, heteroarylalkynyl, substituted heteroarylalkynyl, alkoxy, amine, amide, ether, thioether, ester, thioester, thiolate, phosphide, phosphine, chloride, fluoride, bromide, iodide, cyanate, thiocyanate or cyanide, which could be either monoanionic, cationic, or neutral. When Z₁, Z₂ or Z₃ is nitrogen, R₁, R₂ and R₃ are optionally present or are independently selected from, but not limited to, hydrogen, alkyl, substituted alkyl, alkenyl substituted alkenyl, alkynyl, substituted alkynyl, alkylaryl, substituted alkylaryl, aryl, substituted aryl, alkylalkenyl, substituted alkylalkenyl, arylalkenyl, substituted arylalkenyl, alkylalkynyl, substituted alkylalkynyl, arylalkynyl, substituted arylalkynyl, cycloalkyl, substituted cycloalkyl, cycloalkenyl, substituted cycloalkenyl, cycloalkynyl, substituted cycloalkynyl, heteroaryl, substituted heteroaryl, heterocyclic, substituted heterocyclic, heteroalkylalkynyl, substituted heteroalkylalkynyl, heteroarylalkynyl, substituted heteroarylalkynyl, alkoxy, amine, amide, ether, thioether, ester, thioester, thiolate, phosphide, phosphine, chloride, fluoride, bromide, iodide, cyanate, thiocyanate or cyanide, which could be either monoanionic, cationic, or neutral;
(d) C is an optional σ-donating chemical group;
(e) D is a central part of the dendrons comprising a branch point of component dendrimers;
(f) E is optional surface groups or dendrons of the dendrimers;
(g) F is optional conjugated or non-conjugated linker or branching points of the dendrimers;
(h) n=0 or 1.

In one embodiment, provided herein is a luminescent gold(III) compound having the chemical structure shown in the generic formula (I),

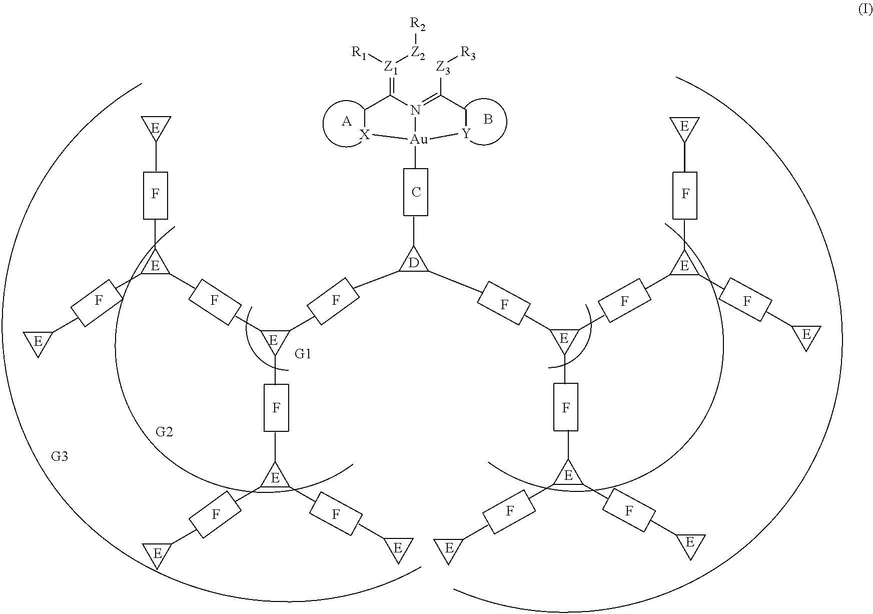

wherein:
(a) X, Y, Z₁, Z₂ and Z₃ are nitrogen or carbon;
(b) A and B are independently cyclic structure derivatives of unsubstituted or substituted phenyl groups or heterocyclic groups;
(c) When Z₁, Z₂ or Z₃ is carbon, R₁, R₂ and R₃ are independently selected from, but not limited to, hydrogen, alkyl, substituted alkyl, alkenyl, substituted alkenyl, alkynyl, substituted alkynyl, alkylaryl, substituted alkylaryl, aryl, substituted aryl, alkylalkenyl, substituted alkylalkenyl, arylalkenyl, substituted arylalkenyl, alkylalkynyl, substituted alkylalkynyl, arylalkynyl, substituted arylalkynyl, cycloalkyl, substituted cycloalkyl, cycloalkenyl, substituted cycloalkenyl, cycloalkynyl, substituted cycloalkynyl, heteroaryl, substituted heteroaryl, heterocyclic, substituted heterocyclic, heteroalkylalkynyl, substituted heteroalkylalkynyl, heteroarylalkynyl, substituted heteroarylalkynyl, alkoxy, amine, amide, ether, thioether, ester, thioester, thiolate, phosphide, phosphine, chloride, fluoride, bromide, iodide, cyanate, thiocyanate or cyanide, which could be either monoanionic, cationic, or neutral. When Z₁, Z₂ or Z₃ is nitrogen, R₁, R₂ and R₃ are optionally present or are independently selected from, but not limited to, hydrogen, alkyl, substituted alkyl, alkenyl substituted alkenyl, alkynyl, substituted alkynyl, alkylaryl, substituted alkylaryl, aryl, substituted aryl, alkylalkenyl, substituted alkylalkenyl, arylalkenyl, substituted arylalkenyl, alkylalkynyl, substituted alkylalkynyl, arylalkynyl, substituted arylalkynyl, cycloalkyl, substituted cycloalkyl, cycloalkenyl, substituted cycloalkenyl, cycloalkynyl, substituted cycloalkynyl, heteroaryl, substituted heteroaryl, heterocyclic, substituted heterocyclic, heteroalkylalkynyl, substituted heteroalkylalkynyl, heteroarylalkynyl, substituted heteroarylalkynyl, alkoxy, amine, amide, ether, thioether, ester, thioester, thiolate, phosphide, phosphine, chloride, fluoride, bromide, iodide, cyanate, thiocyanate or cyanide, which could be either monoanionic, cationic, or neutral;
(d) C is an optional o-donating chemical group;
(e) D is a central part of the dendrons comprising a branch point of component dendrimers;
(f) E is optional surface groups or dendrons of the dendrimers;
(g) F is optional conjugated or non-conjugated linker or branching points of the dendrimers;
(h) n=0 or 1,
wherein the luminescent gold(III) compound comprises TADF and TSDP properties.

In one embodiment, the rings A and B are independently benzene, pyridine, phenyl and pyridyl derivatives, heterocycle or heterocyclic derivatives, but are not limited to, with one or more alkyl, alkenyl, substituted alkenyl, alkynyl, substituted alkynyl, alkylaryl, substituted alkylaryl, aryl, substituted aryl, alkylalkenyl, substituted alkylalkenyl, arylalkenyl, substituted arylalkenyl, alkylalkynyl, substituted alkylalkynyl, arylalkynyl, substituted arylalkynyl, cycloalkyl, substituted cycloalkyl, cycloalkenyl, substituted cycloalkenyl, cycloalkynyl, substituted cycloalkynyl, heteroaryl, substituted heteroaryl, heterocylic, substituted heterocylic, heteroalkylalkynyl, substituted heteroalkylalkynyl, heteroarylalkynyl, substituted heteroarylalkynyl, OR, NR₂, SR, C(O)R, C(O)OR, C(O)NR₂, CN, CF₃, NO₂, SO₂, SOR, SO₃R, halo, or heterocyclic group, wherein R is independently alkyl, alkenyl, alkynyl, alkyaryl, aryl, heteroaryl, heterocylic aryl, heteroalkylalkynyl, heteroalkylalkenyl, heteroarylalkenyl, heteroarylalkynyl, or cycloalkyl.

In one embodiment, the unit C is selected from, but is not limited to, alkyl, alkenyl, substituted alkenyl, alkynyl, substituted alkynyl, alkylaryl, substituted alkylaryl, aryl, substituted aryl, alkylalkenyl, substituted alkylalkenyl, arylalkenyl, substituted arylalkenyl, alkylalkynyl, substituted alkylalkynyl, arylalkynyl, substituted arylalkynyl, cycloalkyl, substituted cycloalkyl, cycloalkenyl, substituted cycloalkenyl, cycloalkynyl, substituted cycloalkynyl, heteroaryl, substituted heteroaryl, heterocylic, substituted heterocylic, heteroalkylalkynyl, substituted heteroalkylalkynyl, heteroarylalkynyl, substituted heteroarylalkynyl, OR, NR₂, SR, C(O)R, C(O)OR, C(O)NR₂, CN, CF₃, NO₂, SO₂, SOR, SO₃R, halo, or heterocyclic group, wherein R is independently alkyl, alkenyl, alkynyl, alkyaryl, aryl, heteroaryl, heterocylic aryl, heteroalkylalkynyl, heteroalkylalkenyl, heteroarylalkenyl, heteroarylalkynyl, or cycloalkyl.

In one embodiment, the units D, E and F are independently benzene, pyridine, phenyl and pyridyl derivatives, heterocycle or heterocyclic derivatives, but are not limited to, with one or more alkyl, alkenyl, substituted alkenyl, alkynyl, substituted alkynyl, alkylaryl, substituted alkylaryl, aryl, substituted aryl, alkylalkenyl, substituted alkylalkenyl, arylalkenyl, substituted arylalkenyl, alkylalkynyl, substituted alkylalkynyl, arylalkynyl, substituted arylalkynyl, cycloalkyl, substituted cycloalkyl, cycloalkenyl, substituted cycloalkenyl, cycloalkynyl, substituted cycloalkynyl, heteroaryl, substituted heteroaryl, heterocylic, substituted heterocylic, heteroalkylalkynyl, substituted heteroalkylalkynyl, heteroarylalkynyl, substituted heteroarylalkynyl, OR, NR₂, SR, C(O)R, C(O)OR, C(O)NR₂, CN, CF₃, NO₂, SO₂, SOR, SO₃R, halo, or heterocyclic group, wherein R is independently alkyl, alkenyl, alkynyl, alkyaryl, aryl, heteroaryl, heterocylic aryl, heteroalkylalkynyl, heteroalkylalkenyl, heteroarylalkenyl, heteroarylalkynyl, or cycloalkyl.

In one embodiment, the gold(III) compound has photoluminescence properties within a range of about 380 to 1050 nm.

In one embodiment, the luminescent gold(III) compound emits light in response to the passage of an electric current through the compound or to a strong electric field.

In one embodiment, the luminescent gold(III) compound comprises photoluminescence properties within a range of about 380 to 1050 nm.

In one embodiment, the gold(III) compound emits light in response to the passage of an electric current through the compound or to a strong electric field.

In certain embodiments, the luminescent gold(III) compound has a chemical structure of compound 1, 2 or 3 having the following formulae:

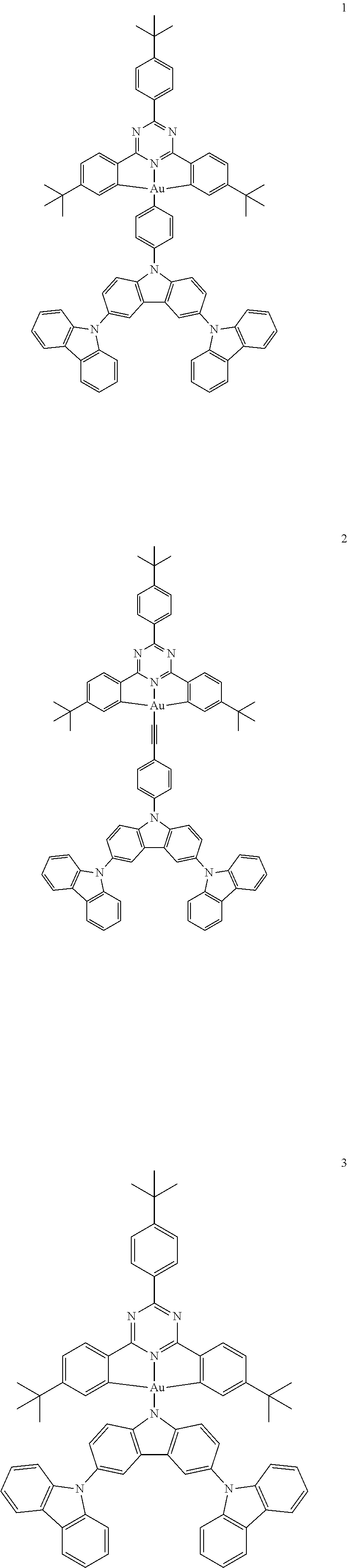

Provided herein is a light-emitting device with a structure comprising an anode, a hole-transporting layer, a light-emitting layer, an electron-transporting layer and a cathode wherein the light-emitting layer comprises a luminescent gold(III) compound.

In one embodiment, the light-emitting layer is prepared using vacuum deposition or solution processing technique.

In one embodiment, the gold(III) compound is deposited as a thin layer on a substrate.

In one embodiment, the gold(III) compound is a dopant in the light-emitting layer or emissive layer.

In one embodiment, the thin layer is deposited by vacuum deposition, spin-coating, or inkjet printing.

In one embodiment, the emission energy of the light-emitting device is dependent on a concentration of the luminescent gold(III) compound and one or more donor groups on an auxiliary ligand, wherein the one or more donor groups are selected from B, C, Si, N, P, O, S, Se, F, Cl, Br, I.

In one embodiment, provided herein is a method for preparing luminescent gold(III) compounds, said method comprising the steps of

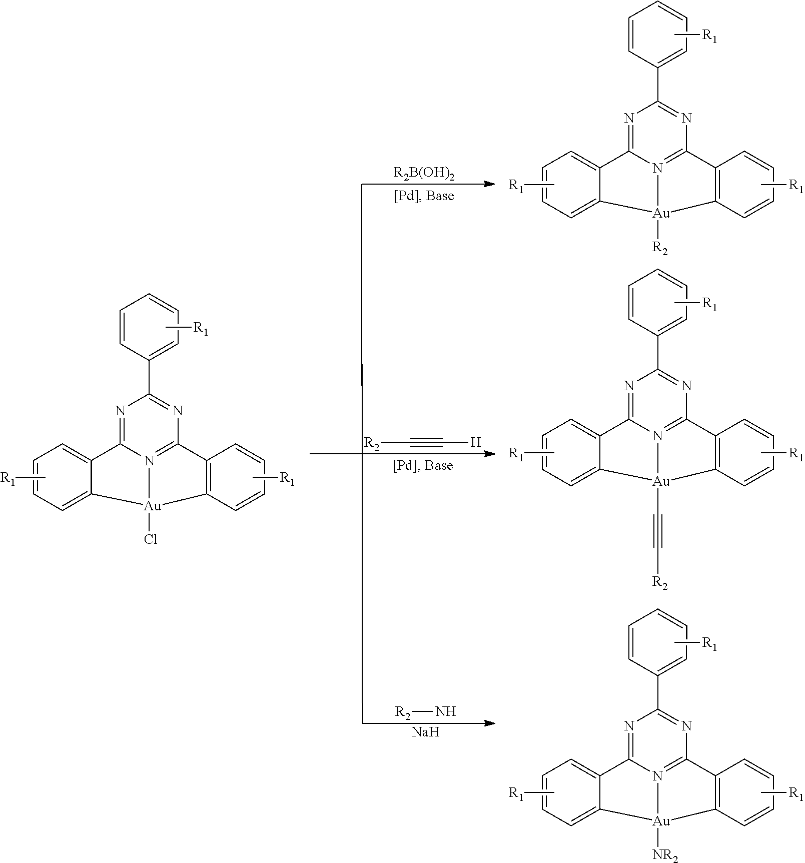

wherein:
(a) R₁ is selected from, but are not limited to, alkyl, alkenyl, alkynyl, alkylaryl, aryl and cycloalkyl with one or more alkyl, alkenyl, alkynyl, alkylaryl, cycloalkyl, OR, NR₂, SR, C(O)R, C(O)OR, C(O)NR₂, CN, CF₃, NO₂, SO₂, SOR, SO₃R, halo, aryl, substituted aryl, heteroaryl, substituted heteroaryl or a heterocyclic group, wherein R is independently alkyl, alkenyl, alkynyl, alkylaryl, aryl or cycloalkyl. R₁ could also be heteroatom and is selected from, but not limited to, boron, carbon, silicon, nitrogen, phosphorus, oxygen, sulphur, selenium, fluorine, chlorine, bromine, or iodine;
(b) R₂ is selected from, but is not limited to, alkyl, substituted alkyl, aryl, substituted aryl, heteroaryl, substituted heteroaryl, heterocyclic, substituted heterocyclic, alkenyl, substituted alkenyl, alkynyl or substituted alkynyl, wherein the heteroaryl or heterocyclic group could have heteroatom selected from, but not limited to, boron, carbon, silicon, nitrogen, phosphorus, oxygen, sulphur, selenium, fluorine, chlorine, bromine, or iodine; and
(c) n is zero, a positive integer or a negative integer.

In one or more embodiments, the compound is deposited as a thin layer on a substrate. For example, the thin layer can be deposited by vacuum deposition, spin-coating, or inkjet printing.

In one or more embodiments, the luminescent gold(III) compounds disclosed herein are deposited as a thin layer on a substrate layer. In one or more embodiments, the thickness of the deposited gold(III) compound is 10-20 nm, 21-30 nm, 31-40 nm, 41-50 nm, 51-60 nm, 61-70 nm, 71-80 nm, 81-90 nm, or 91-100 nm. Further, the compound has photoluminescence properties within a range of about 380 to 1050 nm. In one embodiment, the photoluminescence property of the compound is within a range of about 400 nm to 500 nm. In one embodiment, the photoluminescence property of the compound is within a range of about 500 nm to 600 nm. In one embodiment, the photoluminescence property of the compound is within a range of about 600 nm to 700 nm.

In one or more embodiments, the gold(III) compound is a dopant in the light-emitting layer or emissive layer of an OLED. For example, an emission energy of the OLED can be independent or dependent on the concentration of the gold(III) compound and one or more donor groups on an auxiliary ligand, in which the one or more donor groups are selected from, but not limited to: B, C, Si, N, P, O, S, Se, F, Cl, Br, I.

In certain embodiments, the novel class of gold(III) compounds is highly soluble in common organic solvents, such as dichloromethane, chloroform, toluene and others.

In certain embodiments, the compounds can be non-doped or doped into a host matrix for thin film preparation by either vacuum deposition, spin-coating, ink-jet printing or other known fabrication methods. In some embodiments, the compounds can be used for the fabrication of OLEDs as phosphorescent emitters or dopants to generate EL.

In certain embodiments, the luminescent gold(III) compound is included in a light-emitting layer or emissive layer. The typical structure of an OLED using luminescent compounds of the present disclosure as a light-emitting layer or emissive layer has the following order: cathode/electron-transporting layer/luminescent gold(III) compound or any TSDP emitter as an emissive layer/hole-transporting layer/anode.

In one or more embodiments, the light-emitting layer or emissive layer is prepared using vacuum deposition or solution processing technique.

In certain embodiments, a hole-blocking layer and a carrier confinement layer are employed to improve the device performance. Device structures with modifications to include various carrier blocking layers, carrier injection layer and interlayers are also used to improve the device performance.

Furthermore, a method for preparing luminescent gold(III) compounds.

### BRIEF DESCRIPTION OF THE DRAWINGS

The patent or application file contains at least one drawing executed in color. Copies of this patent or patent application publication with color drawings will be provided by the Office upon request and payment of the necessary fee.

The disclosure is illustrated in the figures of the accompanying drawings which are meant to be exemplary and not limiting, in which like references are intended to refer to like or corresponding parts, and in which:

FIG. 1 is the general schematic diagram for emission processes shown by TADF emitters, TSDP emitters and TADF-TSDP emitters.

FIG. 2 shows the chemical structures of compounds 1-3.

FIG. 3 shows the UV-visible absorption spectra of compounds 1-3 in toluene at 298 K, in accordance with an embodiment of the present invention.

FIG. 4 shows the normalized photoluminescence spectra of compounds 1-3 in toluene at 298 K, in accordance with an embodiment of the present invention.

FIG. 5 shows the solid-state emission spectra of 1 at different temperatures from 220 K to 350 K upon excitation at 365 nm.

FIG. 6 shows the emission spectra of 1 in toluene solution at different temperatures from 190 K to 350 K upon excitation at 365 nm.

FIG. 7 shows the photoluminescence decay lifetime for 1 in solid state at 140-350 K.

### DETAILED DESCRIPTION

One aspect of the subject matter described herein is the novel concept of realization of TADF and TSDP, a.k.a. TADF-TSDP, as well as the development of a new class of a luminescent small-molecular and dendritic gold(III) compounds with TADF and TSDP properties. The small-molecular and dendritic gold(III) compounds are coordination compounds that contain one strong o-donating group and one cyclometalating tridentate ligand, both coordinated to a gold(III) metal center. The gold(III) compounds contain one or more pairs of donor and acceptor with the proximity of the energies of S₁, T₁ and T₁′ excited states.

The subject matter described herein provides another possible way to achieve emission from higher-lying singlet and triplet excited states via a novel concept of using TADF and TSDP mechanisms, in which relatively high luminescence quantum efficiency and short emission lifetime, and potentially longer operational lifetime can be achieved. This TADF-TSDP mechanism is unique and unprecedented, in which both the characteristics of TADF and TSDP, where thermal up-conversion of excitons from lower-energy excited states to higher-energy excited states are observed. But instead of up-conversion from the lowest-energy T₁ to a single emissive state, the up-conversion can take place to both the lowest-energy singlet state S₁ and the second lowest-energy triplet excited state T₁′ (T₁′ refers to a triplet state that has a different excited state origin from T₁; T₁′ will be equivalent to T₂ if it shares the same excited state origin as T₁. For simplicity, only T₁′is used in the following context, which also covers the meaning of T₂) via the RISC and RIC pathway respectively, as illustrated in FIG. 1. In the present invention, with both TADF and TSDP operating, three channels of radiative decay, namely prompt phosphorescence, TADF and TSDP are active, instead of only two channels in the TADF or TSDP alone systems.

In TADF systems, as both the population of T₁ from S₁ and the radiative decay process, i.e. delayed fluorescence, would rely on the respective spin-forbidden ISC and up-conversion via the spin-forbidden RISC to populate the higher-lying S₁ state, which are usually not very efficient without a strong spin-orbit coupling, especially with the lack of heavy metal centres in the pure organic systems, this would inevitably result in long-lived triplet states with lifetimes in hundreds of microseconds to milliseconds range, giving rise to rather long delayed fluorescence lifetimes of purely organic TADF systems. A long emission lifetime will lead to various undesirable excitonic processes, such as exciton-exciton annihilation, exciton-polaron annihilation etc. that will lead to reduced quantum efficiency and even decomposition of emitters. For TSDP compounds, instead of the up-conversion to the singlet state, the excitons are found to be up-converted from T₁ state to T₁′ state through efficient spin-allowed RIC, resulting in phosphorescence with higher energy upon relaxation of the T₁′ state. With the incorporation of heavy metal centre in the TSDP system, the large spin-orbit coupling constant would give rise to efficient ISC, thereby leading to a shorter triplet excited state lifetime relative to the pure organic system. In addition, the more efficient spin-allowed RIC for up-conversion is utilized instead of the spin-forbidden RISC, leading to a faster up-conversion process when compared to TADF. Overall, the emission lifetime can be shortened to the microsecond regime.

In one embodiment of the present disclosure, with both TADF and TSDP operating, three channels of radiative decay, namely prompt phosphorescence, TADF and TSDP are active, instead of only two channels in the TADF or TSDP alone systems. In one embodiment, the extra channel in the present disclosure can increase the overall radiative decay rate constant (kᵣ) by providing multiple pathways for excitons to return to the ground state, giving rise to larger kᵣ, rendering the radiative decay process more competitive relative to the non-radiative decay to result in higher photoluminescence quantum yields as well as shorter-lived excited states. Thus, in certain embodiments, with TADF and TSDP mechanisms, enhanced radiative decay and luminescence from both S₁, T₁ and T₁′ excitons can be resulted, leading to fast radiative decay that can potentially shorten the excited state lifetime to sub-microsecond regime and improve the photoluminescence quantum yield of the complexes and the external quantum efficiency of the corresponding devices. Since both TADF and TSDP involve the up-conversion of excitons from lower-energy states to higher-energy states, in one embodiment, the present disclosure is especially useful for the design of blue-emitting materials, in which high-energy emissive states are required. Specifically, the development of blue-emitting phosphorescent materials is lagging behind as compared to their red- and green-emitting counterparts, particularly in the stability aspect. The low stability of blue emitters usually results in the degradation of OLED devices, causing deterioration of display colors. In one embodiment, the present disclosure provides an alternative strategy towards the realization of stable blue emitters, in addition to emitters of other colors.

Moreover, in one embodiment, dendritic structure is introduced to improve the solubility of this class of complexes. Particularly, in one embodiment, with the highly branched peripheral groups, intermolecular interactions are effectively reduced in dendritic compounds, resulting in suppressed excimeric emission and improved solubility. Thus, in one embodiment, a higher color purity can be achieved, especially for blue emitters. Meanwhile, in one embodiment, taking the advantage of high solubility, thin films of these compounds can be prepared by various solution-processing techniques, such as spin-coating and ink jet printing, which are more cost-effective and suitable for large-area displays as compared to the traditional vacuum deposition technique for the fabrication of OLEDs.

In one embodiment, the present subject matter disclosed herein makes use of this TADF-TSDP mechanism to generate a new class of highly efficient emitters by involving more emissive excited states, as exemplified by the small-molecular and dendritic gold(III) compounds. In certain embodiments, these compounds are potential candidates for the fabrication of high-performance OLEDs that have a higher stability of the emitting materials by reducing the emission lifetime, and higher color purity by incorporation of charge transfer nature, and higher EQE by increasing the photoluminescence quantum yield (PLQY).

In certain embodiments, further disclosed herein is the use of one or more specific donor-acceptor pairs and pincer ligands to achieve close-lying S₁, T₁ and T₁′ excited states and therefore the up-conversion of T₁ excitons to S₁ and T₁′ excited states, and the design, synthesis and luminescence behaviours of gold(III) complexes exhibiting TADF-TSDP properties. Notably, in certain embodiments, excitons are harvested with higher energy from low-energy triplet excitons by up-conversion via RISC to give TADF as well as via RIC to give TSDP. In certain embodiments, the TADF-TSDP mechanism can result in higher PLQYs as well as shorter-lived excited states of the complexes. In certain embodiments, the TADF-TSDP property also provides an alternative strategy towards the realization of stable emitters, in one embodiment, especially for blue emitters.

In certain embodiments, the luminescent gold(III) compounds with TADF-TSDP properties have the chemical structure shown in generic formula (I),

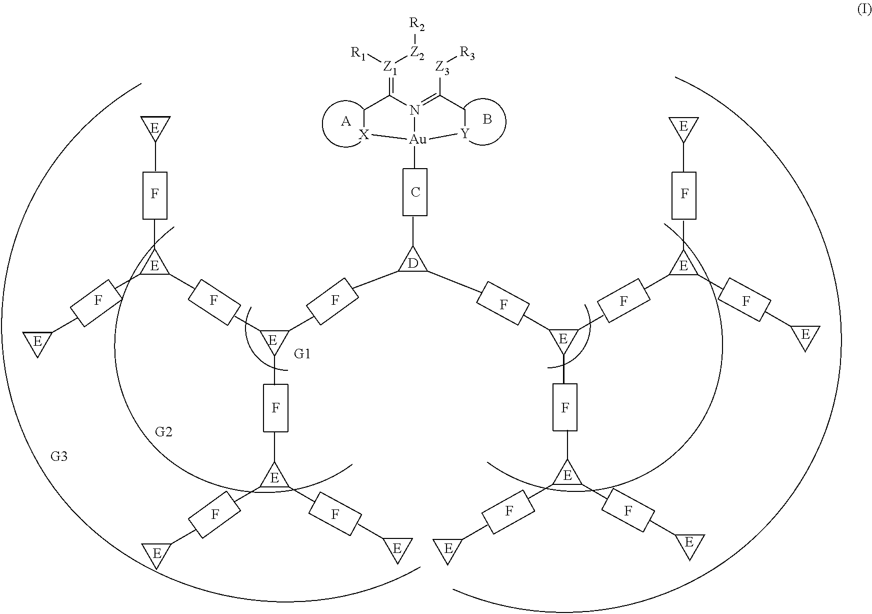

wherein:
(a) X, Y, Z₁, Z₂ and Z₃ are nitrogen or carbon;
(b) A and B are independently cyclic structure derivatives of unsubstituted or substituted phenyl groups or heterocyclic groups;
(c) When Z₁, Z₂ or Z₃ is carbon, R₁, R₂ and R₃ are independently selected from, but not limited to, hydrogen, alkyl, substituted alkyl, alkenyl, substituted alkenyl, alkynyl, substituted alkynyl, alkylaryl, substituted alkylaryl, aryl, substituted aryl, alkylalkenyl, substituted alkylalkenyl, arylalkenyl, substituted arylalkenyl, alkylalkynyl, substituted alkylalkynyl, arylalkynyl, substituted arylalkynyl, cycloalkyl, substituted cycloalkyl, cycloalkenyl, substituted cycloalkenyl, cycloalkynyl, substituted cycloalkynyl, heteroaryl, substituted heteroaryl, heterocyclic, substituted heterocyclic, heteroalkylalkynyl, substituted heteroalkylalkynyl, heteroarylalkynyl, substituted heteroarylalkynyl, alkoxy, amine, amide, ether, thioether, ester, thioester, thiolate, phosphide, phosphine, chloride, fluoride, bromide, iodide, cyanate, thiocyanate or cyanide, which could be either monoanionic, cationic, or neutral. When Z₁, Z₂ or Z₃ is nitrogen, R₁, R₂ and R₃ are optionally present or are independently selected from, but not limited to, hydrogen, alkyl, substituted alkyl, alkenyl substituted alkenyl, alkynyl, substituted alkynyl, alkylaryl, substituted alkylaryl, aryl, substituted aryl, alkylalkenyl, substituted alkylalkenyl, arylalkenyl, substituted arylalkenyl, alkylalkynyl, substituted alkylalkynyl, arylalkynyl, substituted arylalkynyl, cycloalkyl, substituted cycloalkyl, cycloalkenyl, substituted cycloalkenyl, cycloalkynyl, substituted cycloalkynyl, heteroaryl, substituted heteroaryl, heterocyclic, substituted heterocyclic, heteroalkylalkynyl, substituted heteroalkylalkynyl, heteroarylalkynyl, substituted heteroarylalkynyl, alkoxy, amine, amide, ether, thioether, ester, thioester, thiolate, phosphide, phosphine, chloride, fluoride, bromide, iodide, cyanate, thiocyanate or cyanide, which could be either monoanionic, cationic, or neutral;
(d) C is an optional o-donating chemical group;
(e) D is a central part of the dendrons comprising a branch point of component dendrimers;
(f) E is optional surface groups or dendrons of the dendrimers;
(g) F is optional conjugated or non-conjugated linker or branching points of the dendrimers;
(h) n=0 or 1.

In one or more embodiments, rings A and B are independently benzene, pyridine, phenyl and pyridyl derivatives, heterocycle or heterocyclic derivatives, but are not limited to, with one or more alkyl, alkenyl, substituted alkenyl, alkynyl, substituted alkynyl, alkylaryl, substituted alkylaryl, aryl, substituted aryl, alkylalkenyl, substituted alkylalkenyl, arylalkenyl, substituted arylalkenyl, alkylalkynyl, substituted alkylalkynyl, arylalkynyl, substituted arylalkynyl, cycloalkyl, substituted cycloalkyl, cycloalkenyl, substituted cycloalkenyl, cycloalkynyl, substituted cycloalkynyl, heteroaryl, substituted heteroaryl, heterocylic, substituted heterocylic, heteroalkylalkynyl, substituted heteroalkylalkynyl, heteroarylalkynyl, substituted heteroarylalkynyl, OR, NR₂, SR, C(O)R, C(O)OR, C(O)NR₂, CN, CF₃, NO₂, SO₂, SOR, SO₃R, halo, or heterocyclic group, wherein R is independently alkyl, alkenyl, alkynyl, alkyaryl, aryl, heteroaryl, heterocylic aryl, heteroalkylalkynyl, heteroalkylalkenyl, heteroarylalkenyl, heteroarylalkynyl, or cycloalkyl.

In one or more embodiments, C is selected from, but is not limited to, alkyl, alkenyl, substituted alkenyl, alkynyl, substituted alkynyl, alkylaryl, substituted alkylaryl, aryl, substituted aryl, alkylalkenyl, substituted alkylalkenyl, arylalkenyl, substituted arylalkenyl, alkylalkynyl, substituted alkylalkynyl, arylalkynyl, substituted arylalkynyl, cycloalkyl, substituted cycloalkyl, cycloalkenyl, substituted cycloalkenyl, cycloalkynyl, substituted cycloalkynyl, heteroaryl, substituted heteroaryl, heterocylic, substituted heterocylic, heteroalkylalkynyl, substituted heteroalkylalkynyl, heteroarylalkynyl, substituted heteroarylalkynyl, OR, NR₂, SR, C(O)R, C(O)OR, C(O)NR₂, CN, CF₃, NO₂, SO₂, SOR, SO₃R, halo, or heterocyclic group, wherein R is independently alkyl, alkenyl, alkynyl, alkyaryl, aryl, heteroaryl, heterocylic aryl, heteroalkylalkynyl, heteroalkylalkenyl, heteroarylalkenyl, heteroarylalkynyl, or cycloalkyl.

In one or more embodiments, D, E and F are independently benzene, pyridine, phenyl and pyridyl derivatives, heterocycle or heterocyclic derivatives, but are not limited to, with one or more alkyl, alkenyl, substituted alkenyl, alkynyl, substituted alkynyl, alkylaryl, substituted alkylaryl, aryl, substituted aryl, alkylalkenyl, substituted alkylalkenyl, arylalkenyl, substituted arylalkenyl, alkylalkynyl, substituted alkylalkynyl, arylalkynyl, substituted arylalkynyl, cycloalkyl, substituted cycloalkyl, cycloalkenyl, substituted cycloalkenyl, cycloalkynyl, substituted cycloalkynyl, heteroaryl, substituted heteroaryl, heterocylic, substituted heterocylic, heteroalkylalkynyl, substituted heteroalkylalkynyl, heteroarylalkynyl, substituted heteroarylalkynyl, OR, NR₂, SR, C(O)R, C(O)OR, C(O)NR₂, CN, CF₃, NO₂, SO₂, SOR, SO₃R, halo, or heterocyclic group, wherein R is independently alkyl, alkenyl, alkynyl, alkyaryl, aryl, heteroaryl, heterocylic aryl, heteroalkylalkynyl, heteroalkylalkenyl, heteroarylalkenyl, heteroarylalkynyl, or cycloalkyl.

### Definitions

In the present disclosure the following terms are used.

The term “about” when referring to a mathematical value means plus or minus 5% of the mathematical value.

The term “optional” or “optionally” means that the subsequently described event or circumstance may or may not occur, and that the description includes where said event or circumstances occurs and instances in which it does not. For example, “optionally substituted alkyl” includes “alkyl” and “substituted alkyl”, as defined below.

The term “halo”, “halogen” or “halide” as used herein includes fluorine, chlorine, bromine and iodine.

The term “pseudohalide” as used herein includes, but not limited to, cyanate, thiocyanate and cyanide.

The term “alkyl” as used herein includes straight and branched chain alkyl groups, as well as cycloalkyl groups with alkyl groups having a cyclic structure. Preferred alkyl groups are those containing between one to eighteen carbon atoms and includes methyl, ethyl, propyl, isopropyl, butyl, isobutyl, tert-butyl, and other similar compounds. In addition, the alkyl group may be optionally substituted with one or more substituents selected from OR, NR₂, SR, C(O)R, C(O)OR, C(O)NR₂, CN, CF₃, NO₂, SO₂, SOR, SO₃R, halo and cyclic-amino, wherein R is independently alkyl, alkenyl, alkynyl, alkyaryl, aryl, heteroaryl, heterocylic aryl, heteroalkylalkynyl, heteroalkylalkenyl, heteroarylalkenyl, heteroarylalkynyl, or cycloalkyl.

The term “alkenyl” as used herein includes both straight and branched chain alkene radicals. Preferred alkenyl groups are those containing between two and eighteen carbon atoms. In addition, the alkenyl group may be optionally substituted with one or more substituents selected from OR, NR₂, SR, C(O)R, C(O)OR, C(O)NR₂, CN, CF₃, NO₂, SO₂, SOR, SO₃R, halo and cyclic-amino, wherein R is independently alkyl, alkenyl, alkynyl, alkyaryl, aryl, heteroaryl, heterocylic aryl, heteroalkylalkynyl, heteroalkylalkenyl, heteroarylalkenyl, heteroarylalkynyl, or cycloalkyl.

The term “alkynyl” as used herein includes both straight and branched chain alkyne radicals. Preferred alkynyl groups are those containing between two and eighteen carbon atoms. In addition, the alkynyl group may be optionally substituted with one or more substituents selected from OR, NR₂, SR, C(O)R, C(O)OR, C(O)NR₂, CN, CF₃, NO₂, SO₂, SOR, SO₃R, halo and cyclic-amino, wherein R is independently alkyl, alkenyl, alkynyl, alkyaryl, aryl, heteroaryl, heterocylic aryl, heteroalkylalkynyl, heteroalkylalkenyl, heteroarylalkenyl, heteroarylalkynyl, or cycloalkyl.

The term “arylalkynyl” as used herein includes an alkynyl group which has an aromatic group as a substituent. In addition, the arylalkynyl group may be optionally substituted with one or more substituents selected from OR, NR₂, SR, C(O)R, C(O)OR, C(O)NR₂, CN, CF₃, NO₂, SO₂, SOR, SO₃R, halo and cyclic-amino, wherein R is independently alkyl, alkenyl, alkynyl, alkyaryl, aryl, heteroaryl, heterocylic aryl, heteroalkylalkynyl, heteroalkylalkenyl, heteroarylalkenyl, heteroarylalkynyl, or cycloalkyl.

The term “alkylaryl” as used herein includes an aryl group which has an alkyl group as a substituent. In addition, the alkylaryl group may be optionally substituted with one or more substituents selected from OR, NR₂, SR, C(O)R, C(O)OR, C(O)NR₂, CN, CF₃, NO₂, SO₂, SOR, SO₃R, halo and cyclic-amino, wherein R is independently alkyl, alkenyl, alkynyl, alkyaryl, aryl, heteroaryl, heterocylic aryl, heteroalkylalkynyl, heteroalkylalkenyl, heteroarylalkenyl, heteroarylalkynyl, or cycloalkyl.

The term “alkenylaryl” as used herein includes an aryl group which has an alkenyl group as a substituent. In addition, the alkenylaryl group may be optionally substituted with one or more substituents selected from OR, NR₂, SR, C(O)R, C(O)OR, C(O)NR₂, CN, CF₃, NO₂, SO₂, SOR, SO₃R, halo and cyclic-amino, wherein R is independently alkyl, alkenyl, alkynyl, alkyaryl, aryl, heteroaryl, heterocylic aryl, heteroalkylalkynyl, heteroalkylalkenyl, heteroarylalkenyl, heteroarylalkynyl, or cycloalkyl.

The term “arylalkenyl” as used herein includes an aryl group which has an alkenyl unit as the point of attachment to the gold(III) metal center. In addition, the arylalkenyl group may be optionally substituted with one or more substituents selected from OR, NR₂, SR, C(O)R, C(O)OR, C(O)NR₂, CN, CF₃, NO₂, SO₂, SOR, SO₃R, halo and cyclic-amino, wherein R is independently alkyl, alkenyl, alkynyl, alkyaryl, aryl, heteroaryl, heterocylic aryl, heteroalkylalkynyl, heteroalkylalkenyl, heteroarylalkenyl, heteroarylalkynyl, or cycloalkyl.

Aryl alone or in combination includes carbocyclic aromatic systems. The systems may contain one, two or three rings wherein each ring may be attached together in a pendant manner or may be fused. Preferably the rings are 5- or 6- membered rings.

Heteroaryl alone or in combination includes heterocyclic aromatic systems. The systems may contain one, two or three rings wherein each ring may be attached together in a pendant manner or may be fused. Preferably the rings are 5- or 6- membered rings.

Heterocyclic and heterocycle refer to a 3 to 7-membered ring containing at least one heteroatom. This includes aromatic rings including but not limited to pyridine, thiophene, furan, pyrazole, imidazole, oxazole, isoxazole, thiazole, isothiazole, pyrrole, pyrazine, pyridazine, pyrimidine, benzimidazole, benzofuran, benzothiazole, indole, naphthalene, triazole, tetrazole, pyran, thiapyran, oxadiazole, triazine, tetrazine, carbazole, dibenzothiophene, dibenzofuran, fluorine, and non-aromatic rings including but not limited to piperazine, piperidine, and pyrrolidine. The groups of the present disclosure can be substituted or unsubstituted. Preferred substituents include but are not limited to alkyl, alkoxy, aryl.

Heteroatom refers to S, O, N, P, Se, Te, As, Sb, Bi, B, Si and Ge.

Substituted refers to any level of substitution although mono, di- and tri-substitutions are preferred. Preferred substituents include hydrogen, halogen, aryl, alkyl and heteroaryl.

Cyclometalating ligand is a term well known in the art and includes but is not limited to 2,6-diphenylpyridine (C\hat{ }N\hat{ }C), 2,6-bis(4-tert-butylphenyl)pyridine (^{t}BuC\hat{ }N\hat{ }C^{t}Bu), 2,6-diphenyl-4-(2,5-difluorophenyl)pyridine (2,5-F2-C₆H₃-C\hat{ }N\hat{ }C), 2,6-diphenyl-4-p-tolylpyridine (C\hat{ }NTol\hat{ }C), 2,6-diphenyl-4-phenylpyridine (C\hat{ }NPh\hat{ }C), 2,6-bis(4-fluorophenyl)pyridine (FC\hat{ }N\hat{ }CF), 2,6-diphenyl-4-(4-isopropylphenyl)pyridine (4-ⁱPr-Ph-C\hat{ }N\hat{ }C), 2,6-diphenyl-4-(4-nitrophenyl)pyridine (4-NO₂-Ph-C\hat{ }N\hat{ }C), 2,6-diphenyl-4-(4-methoxyphenyl)pyridine (4-OMe-Ph-C\hat{ }N\hat{ }C), 2,6-diphenyl-4-(4-methylyphenyl)pyridine (4-Me-Ph-C\hat{ }N\hat{ }C), 2,6-diphenyl-4-(4-ethylyphenyl)-pyridine (4-Et-Ph-C\hat{ }N\hat{ }C), 2,6-diphenyl-4-(2,3,4-trimethoxyphenyl)pyridine (2,3,4-OMe₃-Ph-C\hat{ }N\hat{ }C), 2,6-bis(4-methoxyphenyl)-4-(4-nitrophenyl)pyridine (4-NO₂-Ph-MeOC\hat{ }N\hat{ }COMe), 2,6-bis(2,4-dichlorophenyl)-4-(4-isopropylphenyl)-pyridine (4-ⁱPr-Ph-C₁₂C\hat{ }N\hat{ }CC₁₂), 2,6-diphenyl-4-(4-tosylphenyl)pyridine (4-OTs-Ph-C\hat{ }N\hat{ }C), 2,6-diphenyl-4-(4-dimethylaminophenyl)pyridine (4-NMe₂-Ph-C\hat{ }N\hat{ }C), 2,6-diphenyl-4-(4-diphenylaminophenyl)pyridine (4-NPh₂-Ph-C\hat{ }N\hat{ }C), 2,6-diphenyl-4-(4-bromophenyl)pyridine (4-Br-Ph-C\hat{ }N\hat{ }C), 2,6-diphenyl-4-(4-chlorophenyl)pyridine (4-Cl-Ph-C\hat{ }N\hat{ }C), 2,6-diphenyl-4-(4-flurophenyl)pyridine (4-F-Ph-C\hat{ }N\hat{ }C), 2,6-diphenyl-4-(4-iodophenyl)pyridine (4-I-Ph-C\hat{ }NºC), 2,6-diphenyl-4-(2,5-dimethylphenyl)pyridine (2,5-Me₂-Ph-C\hat{ }N\hat{ }C), 2,6-diphenyl-4-(2,3,4,5,6-pentafluorophenyl)pyridine (2,3,4,5,6-F₅-Ph-C\hat{ }N\hat{ }C), 1,3-diphenylisoquinoline (dpiq), 2,4,6- triphenyl-1,3,5-triazine (C\hat{ }N^{TRZ}\hat{ }C), 2,4,6-tris(4-(tert-butyl)phenyl)-1,3,5-triazine (^{t}BuC\hat{ }N^{TRZ}(C₆H₄-^{t}Bu)\hat{ }C^{t}Bu), 2,6-diphenylpyrazine (C\hat{ }N^{PY}\hat{ }C).

Benzene includes substituted or unsubstituted benzene.

Pyridine includes substituted or unsubstituted pyridine.

Thiophene includes substituted or unsubstituted thiophene.

Furan includes substituted or unsubstituted furan.

Pyrazole includes substituted or unsubstituted pyrazole.

Imidazole includes substituted or unsubstituted imidazole.

Oxazole includes substituted or unsubstituted oxazole.

Isoxazole includes substituted or unsubstituted isoxazole.

Thiazole includes substituted or unsubstituted thiazole.

Isothiazole includes substituted or unsubstituted isothiazole.

Pyrrole includes substituted or unsubstituted pyrrole.

Pyrazine includes substituted or unsubstituted pyrazine.

Pyridazine includes substituted or unsubstituted pyridazine.

Pyrimidine includes substituted or unsubstituted pyrimidine.

Benzimidazole includes substituted or unsubstituted benzimidazole.

Benzofuran includes substituted or unsubstituted benzofuran.

Benzothiazole includes substituted or unsubstituted benzothiazole.

Indole includes substituted or unsubstituted indole.

Naphthalene includes substituted or unsubstituted naphthalene.

Triazole includes substituted or unsubstituted triazole.

Tetrazole includes substituted or unsubstituted tetrazole.

Pyran includes substituted or unsubstituted pyran.

Thiapyran includes substituted or unsubstituted thiapyran.

Oxadiazole includes substituted or unsubstituted oxadiazole.

Triazine includes substituted or unsubstituted triazine.

Tetrazine includes substituted or unsubstituted tetrazine.

Carbazole includes substituted or unsubstituted carbazole.

Dibenzothiophene includes substituted or unsubstituted dibenzothiophene.

Dibenzofuran includes substituted or unsubstituted dibenzofuran.

Piperazine includes substituted or unsubstituted piperazine.

Piperidine includes substituted or unsubstituted piperidine.

Pyrrolidine includes substituted or unsubstituted pyrrolidine.

In some embodiments, the luminescent small-molecular and dendritic gold(III) compounds of general structure (I) are prepared in high purity. The compounds described have been represented throughout by their monomeric structure. As is well known to those skilled in the art, the compounds may also be present as dimers, trimers or dendrimers.

The present disclosure will be illustrated more specifically by the following non-limiting examples, it being understood that changes and variations can be made therein without deviating from the scope and the spirit of the disclosure as hereinafter claimed. It is also understood that various theories as to why the disclosure works are not intended to be limiting.

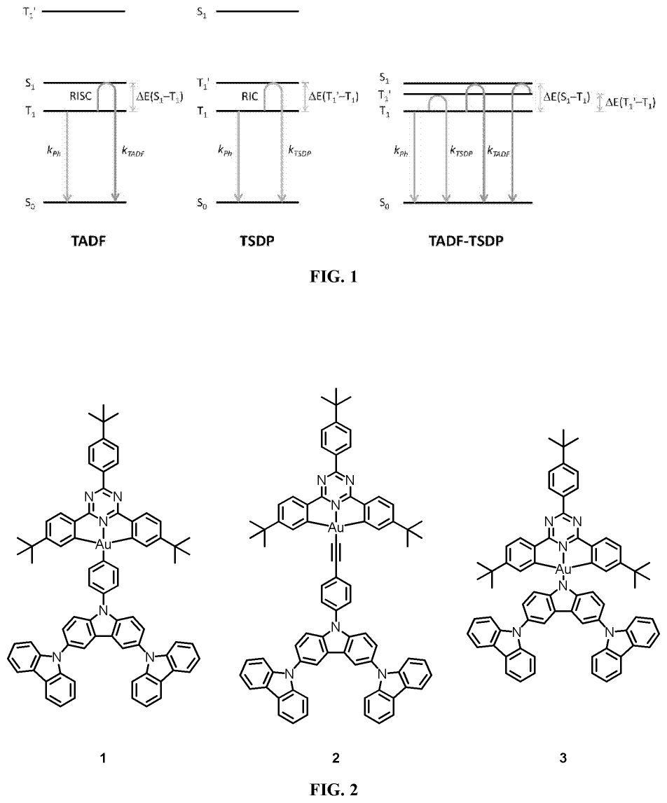

Throughout the following examples, reference is made to FIG. 2, which discloses the chemical structure of a series of compounds that form the basis of the examples, namely compounds 1-3.

### EXAMPLES

### Example 1

General Synthetic Methodology:

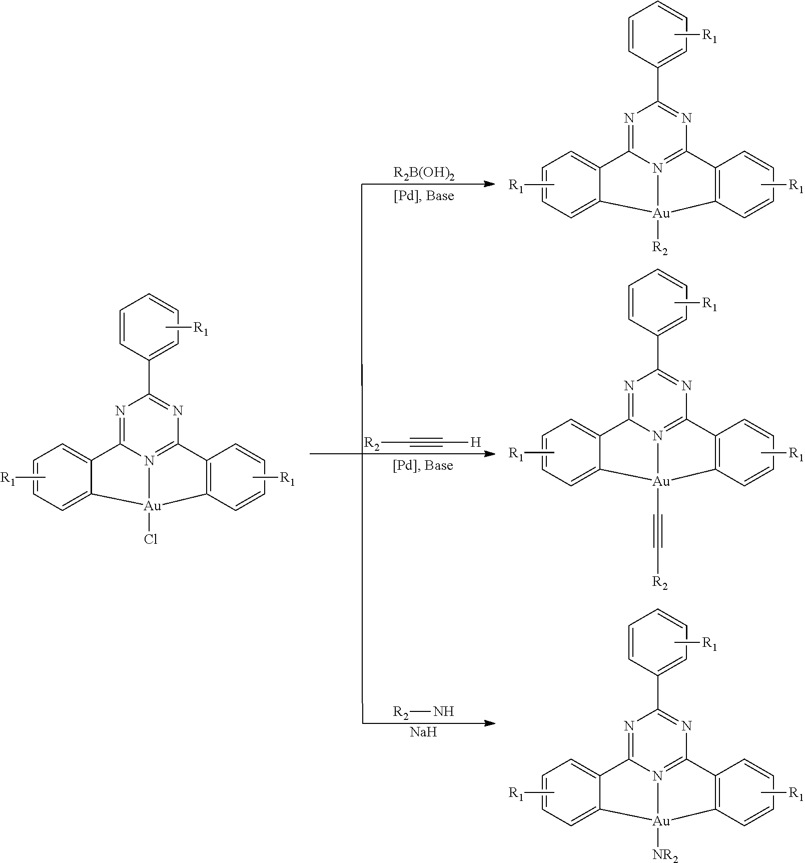

wherein:
(a) R₁ is selected from, but are not limited to, alkyl, alkenyl, alkynyl, alkylaryl, aryl and cycloalkyl with one or more alkyl, alkenyl, alkynyl, alkylaryl, cycloalkyl, OR, NR₂, SR, C(O)R, C(O)OR, C(O)NR₂, CN, CF₃, NO₂, SO₂, SOR, SO₃R, halo, aryl, substituted aryl, heteroaryl, substituted heteroaryl or a heterocyclic group, wherein R is independently alkyl, alkenyl, alkynyl, alkylaryl, aryl or cycloalkyl. R₁ could also be heteroatom and is selected from, but not limited to, nitrogen, oxygen, sulphur or phosphorus;
(b) R₂ is selected from, but is not limited to, alkyl, substituted alkyl, aryl, substituted aryl, heteroaryl, substituted heteroaryl, heterocyclic, substituted heterocyclic, alkenyl, substituted alkenyl, alkynyl or substituted alkynyl; and
(c) n is zero, a positive integer or a negative integer.

Synthesis and Characterization:

The precursor compound, [Au{^{t}BuC\hat{ }N^{TRZ}(C₆H₄-^{t}Bu)\hat{ }C^{t}Bu}Cl] was prepared according to modification of procedures reported in the literature [Wong, K.-H.; Cheung, K.-K.; Chan, M. C.-W.; Che, C.-M. Organometallics 17, 3505 (1998); Tanaka, H.; Shizu, K.; Nakanotani, H.; Adachi, C. J. Phys. Chem. C 118, 15985 (2014)].

¹H NMR spectra were recorded on a Bruker AVANCE 500 (500 MHz) Fourier-transform NMR spectrometer with chemical shifts reported relative to tetramethylsilane (δ0 ppm). The results of the analyses confirm the high purity of compounds 1-3.

Characterization data of compounds 1-3 are as follows:

Compound 1: The target compound was synthesized according to a procedure reported in the literature with modification [Tang, M.-C.; Lee, C.-H.; Lai, S.-L.; Ng, M.; Chan, M.-Y.; Yam, V. W.-W. J. Am. Chem. Soc. 139, 9341 (2017)]. A mixture of [Au{^{t}BuC\hat{ }N^{TRZ}(C₆H₄-^{t}Bu)\hat{ }C^{t}Bu}Cl], K₂CO₃, Pd(OAc)₂, [HP(^{t}Bu)₃]BF₄, and the corresponding boronic acid was stirred in degassed tetrahydrofuran-H₂O (45 mL, 8:1, v/v) at 80° C. under a nitrogen atmosphere, followed by column chromatography to give a yellow solid. The product was further purified by dissolving in dichloromethane and layering with methanol. The solid was filtered and dried under vacuum to give a yellow solid. Yield: 70 mg, 20%. ¹H NMR (500 MHz, CDCl₃, 298 K, relative to Me₄Si, δ/ppm) δ8.72 (d, J=8.0 Hz, 2H), 8.32 (s, 2H), 8.26 (d, J=8.1 Hz, 2H), 8.18 (d, J=7.8 Hz, 4H), 8.10 (d, J=7.8 Hz, 2H), 7.81-7.80 (m, 4H), 7.75 (d, J=7.7 Hz, 2H), 7.66 (t, J=7.2 Hz, 4H), 7.50-7.48 (m, 2H), 7.44-7.42 (m, 8H), 7.31-7.28 (m, 4H), 1.43 (s, 9H), 1.37 (s, 18H).

Compound 2: The target compound was synthesized according to a procedure reported in the literature with modification [Wong, K.-H.; Cheung, K.-K.; Chan, M. C.-W.; Che, C.-M. Organometallics 17, 3505 (1998)]. A mixture of [Au{^{t}BuC\hat{ }N^{TRZ}(C₆H₄-^{t}Bu)\hat{ }C^{t}Bu}Cl], CuI and the corresponding acetylene was stirred in degassed dichloromethane at room temperature under a nitrogen atmosphere, followed by column chromatography to give a yellow solid. The product was further purified by dissolving in dichloromethane and layering with methanol. The solid was filtered and dried under vacuum to give a yellow solid. Yield: 200 mg, 56%. ¹H NMR (500 MHz, CDCl₃, 298 K, relative to Me₄Si, δ/ppm) δ8.68 (d, J=8.3 Hz, 2H), 8.38 (s, 2H), 8.29 (s, 2H), 8.20-8.14 (m, 6H), 7.96 (d, J=8.3 Hz, 2H), 7.75-7.74 (m, 4H), 7.66-7.63 (m, 4H), 7.53-7.49 (m, 2H), 7.42-7.41 (m, 8H), 7.30-7.28 (m, 4H), 1.48 (s, 18H), 1.42 (s, 9H).

Compound 3: The target compound was synthesized according to a procedure reported in the literature with modification [Li, L.-K.; Tang, M.-C.; Lai, S.-L.; Ng, M.; Kwok, W.-K.; Chan, M.-Y.; Yam, V. W.-W. Nature Photon 13, 185 (2019)]. A mixture of [Au{^{t}BuC\hat{ }N^{TRZ}(C₆H₄-^{t}Bu)\hat{ }C^{t}Bu}Cl], NaH and the corresponding carbazole was stirred in degassed dry tetrahydrofuran at room temperature under a nitrogen atmosphere, followed by column chromatography to give a red solid. The product was further purified by dissolving in dichloromethane and layering with methanol. The solid was filtered and dried under vacuum to give a pink solid. Yield: 165 mg, 50%. ¹H NMR (500 MHz, CDCl₃, 298 K, relative to Me₄Si, δ/ppm) δ8.74 (d, J=8.5 Hz, 2H), 8.32 (d, J=1.9 Hz, 2H), 8.22 (d, J=8.0 Hz, 2H), 8.17 (d, J=7.7 Hz, 4H), 7.79 (d, J=8.5 Hz, 2H), 7.68 (d, J=8.5 Hz, 2H), 7.50-7.47 (m, 6H), 7.44-7.38 (m, 10H), 7.28-7.27 (m, 2H), 1.44 (s, 9H), 1.25 (s, 18H).

### Example 2

### UV-Vis Absorption Properties

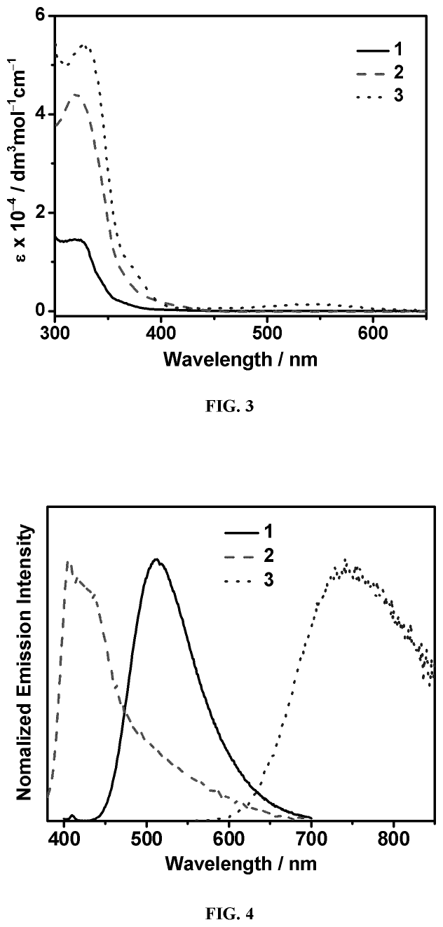

The UV-vis absorption spectra of compounds 1-3 in toluene at 298 K are used for illustration purposes (FIG. 3). In general, all the complexes show intense absorption bands at ca. 290-330 nm with extinction coefficients (ε) in the order of 10⁴ dm³mol⁻¹cm⁻¹. The absorption band is tentatively assigned as the intraligand (IL) π→π* transition of the aromatic moieties. A weak absorption shoulder at ca. 360-400 nm can also be found and can be assigned as the IL charge transfer (ILCT) transition of the cyclometalating tridentate ligands from the aryl ring to the triazine moiety that mixed with the ligand-to-ligand charge transfer (LLCT) π[auxiliary ligand]→π*[C\hat{ }N\hat{ }C] transition. Compound 3 show a lower-energy absorption band at 542 nm, that can be assigned as the LLCT π[auxiliary ligand]→π*[C\hat{ }N\hat{ }C] transition. These assignments are in agreement with the structurally-related gold(III) complexes. The UV-visible absorption data of compounds 1-3 in dichloromethane at 298 K have been summarized in TABLE 1. The UV-vis absorption and emission spectra of compounds 1-3 provide the fundamental photophysical data that offer useful guidelines for the design of the chemical structures to tune the emission color of the emitters in both the solution and the solid state.

### Example 3

### Emission Properties

Upon excitation with λ≥400 nm in degassed toluene, compounds 1-3 are found to be emissive with emission peak maxima ranging from 406 nm to 743 nm (TABLE 1). The emission spectra in degassed toluene solution are shown in FIG. 4. Compounds 1 and 3 show Gaussian-shaped emission bands, while compound 2 shows vibronic-structured emission band. The emission of compounds 1 and 3 can be assigned as originating from the ³LLCT π[auxiliary ligand]→π*[C\hat{ }N\hat{ }C] excited state. On the other hand, the vibronic-structured emission bands of 1 display vibrational progressional spacings of ca. 1370 cm⁻¹, which match with the skeletal vibrational frequencies of the cyclometalating ligand and the emission bands are insensitive towards the nature of the auxiliary ligand. Hence, the emission of compound 1 can be ascribed to be originated from the IL π→π*[C\hat{ }N\hat{ }C] excited state. Solid-state thin film emission studies have also been carried out for compounds 1 and 2 by doping into N,N′-dicarbazolyl-3,5-benzene (MCP) host at 5 wt %. Gaussian shaped emission band at 491 nm for compound 1 and 509 nm for compound 2 are observed. Notably, complex 1 shows intense green emission with CIE coordinates of (0.28, 0.53) while complex 2 shows deep blue emission with CIE coordinates of (0.20, 0.17).

TABLE 1
Photophysical data for compounds 1-3

| | Medium | Absorption λₘₐₓ/nm | Emission |
|---|---|---|---|
| Compound | (T/K) | (εₘₐₓ/dm³mol⁻¹cm⁻¹) | λₘₐₓ/nm |
| 1 | Toluene (298) | 295 (19140), 323 | 512 |
| | Thin film (298) | (14410), 363 (1790) | 491 |
| | 5% in MCP | | |
| 2 | Toluene (298) | 295 (48340), 320 | 406, 430 |
| | Thin film (298) | (44000), 369 (6130) | 509 |
| | 5% in MCP | | |
| 3 | Toluene (298) | 297 (66630), 328 (54260), | 745 |
| | | 377 (7980), 542 (1660) | |

### Example 4

### Temperature-Dependent Emission Properties

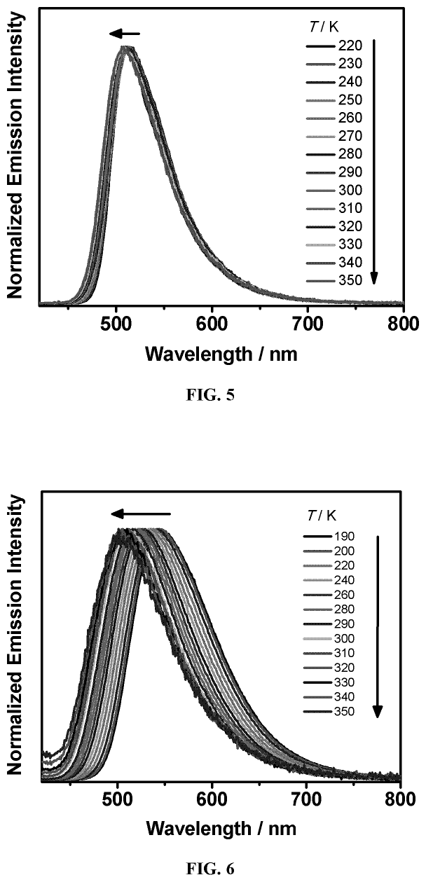

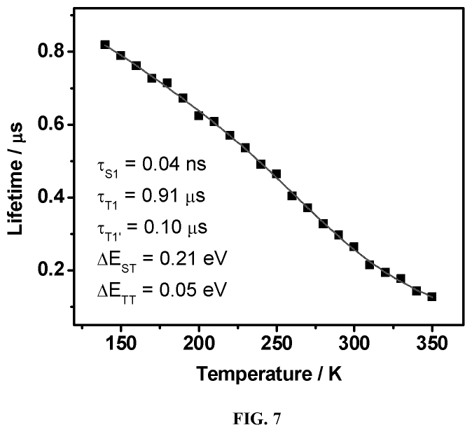

To confirm the occurrence of the TADF-TSDP mechanism, temperature-dependent emission properties of the gold(III) compounds in solid state have been investigated and compound 1 is used for illustration. The emission spectra of compounds 1 in the solid state at different temperatures from 220 K to 350 K, and in toluene solution from 190 K to 350 K, are shown in FIGS. 5-6, respectively. In general, a progressive blue shift of emission bands of compound 1 in both states is observed upon increasing the temperature. Specifically, the thermal energy of molecules at low temperatures is significantly reduced, and the process of up-conversion is no longer or only partially allowed via thermal equilibrium. This results in emission band mixing of the S₁, T₁ and T₁ excited states, given the energies of the three excited states are in close proximity. S₁ excited state is originated predominantly from the ¹ILCT state, T₁ excited state is originated predominantly from the ³ILCT state (with some mixing of ³LLCT character), and T₁′ excited state is originated predominantly from the ³IL (π→π*) state (with some mixing of ³ILCT and ³LLCT characters), respectively. Upon increasing temperature, it is anticipated that more excitons can gain enough thermal energy to overcome the energy gap ΔE(S₁−T₁) between S₁ and T₁ excited states, and ΔE(T₁′−T₁) between T₁ and T₁′ excited states, yielding a blue-shifted emission band from the S₁ and/or T₁′excited state. To further identify of origin of such thermally enhanced luminescence behavior, temperature-dependent lifetime studies have been conducted on solids of compound 1. The data have been evaluated using the following three-level Boltzmann model:

$$τ = \frac{3 + 3 exp \frac{- Δ E ( {T}_{1}^{′} - {T}_{1} )}{{k}_{B} T} + exp \frac{- Δ E ( {S}_{1} - {T}_{1} )}{{k}_{B} T}}{\frac{3}{{τ}_{{T}_{1}}} + \frac{3}{{τ}_{{T}_{1}^{′}}} exp \frac{- Δ E ( {T}_{1}^{′} - {T}_{1} )}{{k}_{B} T} + \frac{1}{{τ}_{{S}_{1}}} exp \frac{- Δ E ( {S}_{1} - {T}_{1} )}{{k}_{B} T}}$$

where k_{B} is Boltzmann constant, T is temperature, τ_{S}_{₁}, τ_{T}_{₁} and τ_{T}_{₁}_{′} are emission lifetimes of S₁, T₁ and T₁′ states, respectively. The model assumes the presence of three emitting states, corresponding to the cases of TADF-TSDP. The two triplet excited states involved in the three-level model are assumed to be in one-to-one ratio. The zero-field splitting (ZFS) of the triplet states is not considered since the splitting into sub-states usually occurs at temperature lower than 50 K, which is out of the range of temperature in the current study. As shown in FIG. 7, the plot of emission lifetime of compound 1 against temperature is well-fitted with the three- level model. The lifetimes, τ_{S}_{₁}, τ_{T}_{₁}, and τ_{T}_{₁}_{′}, are estimated to be 0.04 ns, 0.91 μs and 0.10 μs, respectively, and the energy gaps ΔE(S₁−T₁) and ΔE(T₁′−T₁) are estimated to be 0.21 eV and 0.05 eV, respectively. The short lifetime of the S₁ state in nanosecond, and the relatively longer lifetimes of T₁ and T₁′ states in microsecond to sub-microsecond regime, are in agreement with their nature. The relatively larger ΔE(S₁−T₁) also supports the realization of TSDP, as the larger gap prevents a very fast radiative decay of the excitons through TADF, allowing the excitons to have the chance to reach the higher-lying T₁′ state, which is found to be very close to the T₁ state.

The foregoing description of the specific embodiments will so fully reveal the general nature of the disclosure that others can, by applying knowledge within the skill of the relevant art(s) (including the contents of the documents cited and incorporated by reference herein), readily modify and/or adapt for various applications such specific embodiments, without undue experimentation, without departing from the general concept of the present disclosure. Such adaptations and modifications are therefore intended to be within the meaning and range of equivalents of the disclosed embodiments, based on the teaching and guidance presented herein.

It is to be understood that the phraseology or terminology herein is for the purpose of description and not of limitation, such that the terminology or phraseology of the present specification is to be interpreted by the skilled artisan in light of the teachings and guidance presented herein, in combination with the knowledge of one skilled in the relevant art(s).

While various embodiments of the present disclosure have been described above, it should be understood that they have been presented by way of examples, and not limitation. It would be apparent to one skilled in the relevant art(s) that various changes in form and detail could be made therein without departing from the spirit and scope of the disclosure. Thus, the present disclosure should not be limited by any of the above-described exemplary embodiments, but should be defined only in accordance with the following claims and their equivalents.

What is claimed:

1. A luminescent gold(III) compound having the chemical structure shown in the generic formula (I), 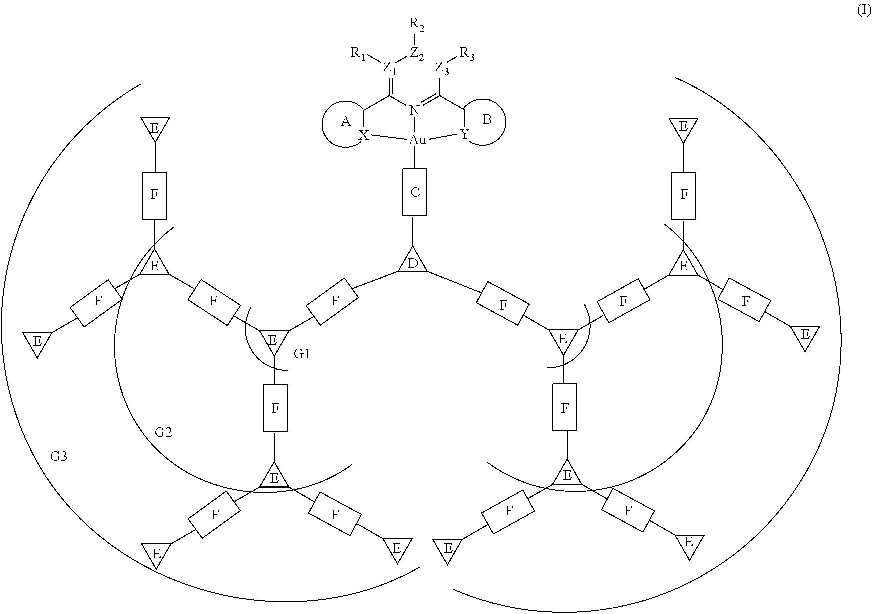
wherein:
(i) X, Y, Z₁, Z₂ and Z₃ are nitrogen or carbon;
(j) A and B are independently cyclic structure derivatives of unsubstituted or substituted phenyl groups or heterocyclic groups;
(k) When Z₁, Z₂ or Z₃ is carbon, R₁, R₂ and R₃ are independently selected from, but not limited to, hydrogen, alkyl, substituted alkyl, alkenyl, substituted alkenyl, alkynyl, substituted alkynyl, alkylaryl, substituted alkylaryl, aryl, substituted aryl, alkylalkenyl, substituted alkylalkenyl, arylalkenyl, substituted arylalkenyl, alkylalkynyl, substituted alkylalkynyl, arylalkynyl, substituted arylalkynyl, cycloalkyl, substituted cycloalkyl, cycloalkenyl, substituted cycloalkenyl, cycloalkynyl, substituted cycloalkynyl, heteroaryl, substituted heteroaryl, heterocyclic, substituted heterocyclic, heteroalkylalkynyl, substituted heteroalkylalkynyl, heteroarylalkynyl, substituted heteroarylalkynyl, alkoxy, amine, amide, ether, thioether, ester, thioester, thiolate, phosphide, phosphine, chloride, fluoride, bromide, iodide, cyanate, thiocyanate or cyanide, which could be either monoanionic, cationic, or neutral. When Z₁, Z₂ or Z₃ is nitrogen, R₁, R₂ and R₃ are optionally present or are independently selected from, but not limited to, hydrogen, alkyl, substituted alkyl, alkenyl substituted alkenyl, alkynyl, substituted alkynyl, alkylaryl, substituted alkylaryl, aryl, substituted aryl, alkylalkenyl, substituted alkylalkenyl, arylalkenyl, substituted arylalkenyl, alkylalkynyl, substituted alkylalkynyl, arylalkynyl, substituted arylalkynyl, cycloalkyl, substituted cycloalkyl, cycloalkenyl, substituted cycloalkenyl, cycloalkynyl, substituted cycloalkynyl, heteroaryl, substituted heteroaryl, heterocyclic, substituted heterocyclic, heteroalkylalkynyl, substituted heteroalkylalkynyl, heteroarylalkynyl, substituted heteroarylalkynyl, alkoxy, amine, amide, ether, thioether, ester, thioester, thiolate, phosphide, phosphine, chloride, fluoride, bromide, iodide, cyanate, thiocyanate or cyanide, which could be either monoanionic, cationic, or neutral;
(l) C is an optional o-donating chemical group;
(m) D is a central part of the dendrons comprising a branch point of component dendrimers;
(n) E is optional surface groups or dendrons of the dendrimers;
(o) F is optional conjugated or non-conjugated linker or branching points of the dendrimers;
(p) n=0 or 1,
wherein the luminescent gold(III) compound comprises TADF and TSDP properties.

2. The luminescent gold(III) compound according to claim 1, wherein rings A and B are independently benzene, pyridine, phenyl and pyridyl derivatives, heterocycle or heterocyclic derivatives, but are not limited to, with one or more alkyl, alkenyl, substituted alkenyl, alkynyl, substituted alkynyl, alkylaryl, substituted alkylaryl, aryl, substituted aryl, alkylalkenyl, substituted alkylalkenyl, arylalkenyl, substituted arylalkenyl, alkylalkynyl, substituted alkylalkynyl, arylalkynyl, substituted arylalkynyl, cycloalkyl, substituted cycloalkyl, cycloalkenyl, substituted cycloalkenyl, cycloalkynyl, substituted cycloalkynyl, heteroaryl, substituted heteroaryl, heterocylic, substituted heterocylic, heteroalkylalkynyl, substituted heteroalkylalkynyl, heteroarylalkynyl, substituted heteroarylalkynyl, OR, NR₂, SR, C(O)R, C(O)OR, C(O)NR₂, CN, CF₃, NO₂, SO₂, SOR, SO₃R, halo, or heterocyclic group, wherein R is independently alkyl, alkenyl, alkynyl, alkyaryl, aryl, heteroaryl, heterocylic aryl, heteroalkylalkynyl, heteroalkylalkenyl, heteroarylalkenyl, heteroarylalkynyl, or cycloalkyl.

3. The luminescent gold(III) compound according to claim 1, wherein unit C is selected from, but is not limited to, alkyl, alkenyl, substituted alkenyl, alkynyl, substituted alkynyl, alkylaryl, substituted alkylaryl, aryl, substituted aryl, alkylalkenyl, substituted alkylalkenyl, arylalkenyl, substituted arylalkenyl, alkylalkynyl, substituted alkylalkynyl, arylalkynyl, substituted arylalkynyl, cycloalkyl, substituted cycloalkyl, cycloalkenyl, substituted cycloalkenyl, cycloalkynyl, substituted cycloalkynyl, heteroaryl, substituted heteroaryl, heterocylic, substituted heterocylic, heteroalkylalkynyl, substituted heteroalkylalkynyl, heteroarylalkynyl, substituted heteroarylalkynyl, OR, NR₂, SR, C(O)R, C(O)OR, C(O)NR₂, CN, CF₃, NO₂, SO₂, SOR, SO₃R, halo, or heterocyclic group, wherein R is independently alkyl, alkenyl, alkynyl, alkyaryl, aryl, heteroaryl, heterocylic aryl, heteroalkylalkynyl, heteroalkylalkenyl, heteroarylalkenyl, heteroarylalkynyl, or cycloalkyl.

4. The luminescent gold(III) compound according to claim 1, wherein units D, E and F are independently benzene, pyridine, phenyl and pyridyl derivatives, heterocycle or heterocyclic derivatives, but are not limited to, with one or more alkyl, alkenyl, substituted alkenyl, alkynyl, substituted alkynyl, alkylaryl, substituted alkylaryl, aryl, substituted aryl, alkylalkenyl, substituted alkylalkenyl, arylalkenyl, substituted arylalkenyl, alkylalkynyl, substituted alkylalkynyl, arylalkynyl, substituted arylalkynyl, cycloalkyl, substituted cycloalkyl, cycloalkenyl, substituted cycloalkenyl, cycloalkynyl, substituted cycloalkynyl, heteroaryl, substituted heteroaryl, heterocylic, substituted heterocylic, heteroalkylalkynyl, substituted heteroalkylalkynyl, heteroarylalkynyl, substituted heteroarylalkynyl, OR, NR₂, SR, C(O)R, C(O)OR, C(O)NR₂, CN, CF₃, NO₂, SO₂, SOR, SO₃R, halo, or heterocyclic group, wherein R is independently alkyl, alkenyl, alkynyl, alkyaryl, aryl, heteroaryl, heterocylic aryl, heteroalkylalkynyl, heteroalkylalkenyl, heteroarylalkenyl, heteroarylalkynyl, or cycloalkyl.

5. The luminescent gold(III) compound according to claim 1, wherein the gold(III) compound has photoluminescence properties within a range of about 380 to 1050 nm.

6. The luminescent gold(III) compound according to claim 1, wherein the gold(III) compound emits light in response to the passage of an electric current through the compound or to a strong electric field.

7. The luminescent gold(III) compound according to claim 1 having photoluminescence properties within a range of about 380 to 1050 nm.

8. The luminescent gold(III) compound according to claim 1, wherein the gold(III) compound emits light in response to the passage of an electric current through the compound or to a strong electric field.

9. A luminescent gold(III) compound having a chemical structure of compound 1, 2 or 3 having the following formulae:

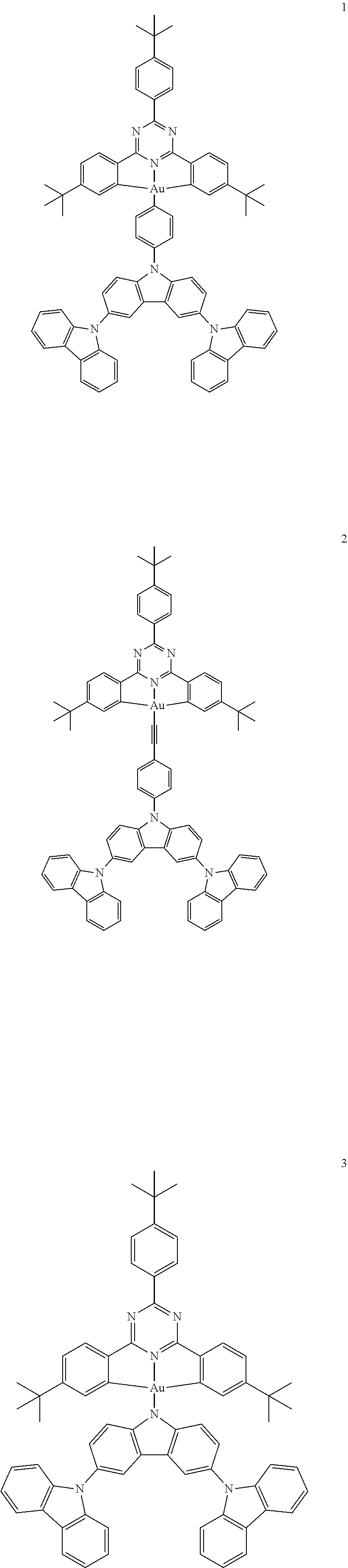

10. A light-emitting device with a structure comprising an anode, a hole-transporting layer, a light-emitting layer, an electron-transporting layer and a cathode wherein the light-emitting layer comprises a luminescent gold(III) compound of claim 1.

11. The light-emitting device of claim 10, wherein the light-emitting layer is prepared using vacuum deposition or solution processing technique.

12. The light-emitting device of claim 10, wherein the gold(III) compound is deposited as a thin layer on a substrate.

13. The light-emitting device of claim 10, wherein the gold(III) compound is a dopant in the light-emitting layer or emissive layer.

14. The light-emitting device of claim 10, wherein the thin layer is deposited by vacuum deposition, spin-coating, or inkjet printing.

15. The light-emitting device of claim 10, wherein an emission energy of the light-emitting device is dependent on a concentration of the luminescent gold(III) compound and one or more donor groups on an auxiliary ligand, wherein the one or more donor groups are selected from B, C, Si, N, P, O, S, Se, F, Cl, Br, I.

16. A method for preparing luminescent gold(III) compounds of claim 1, said method comprising the steps of 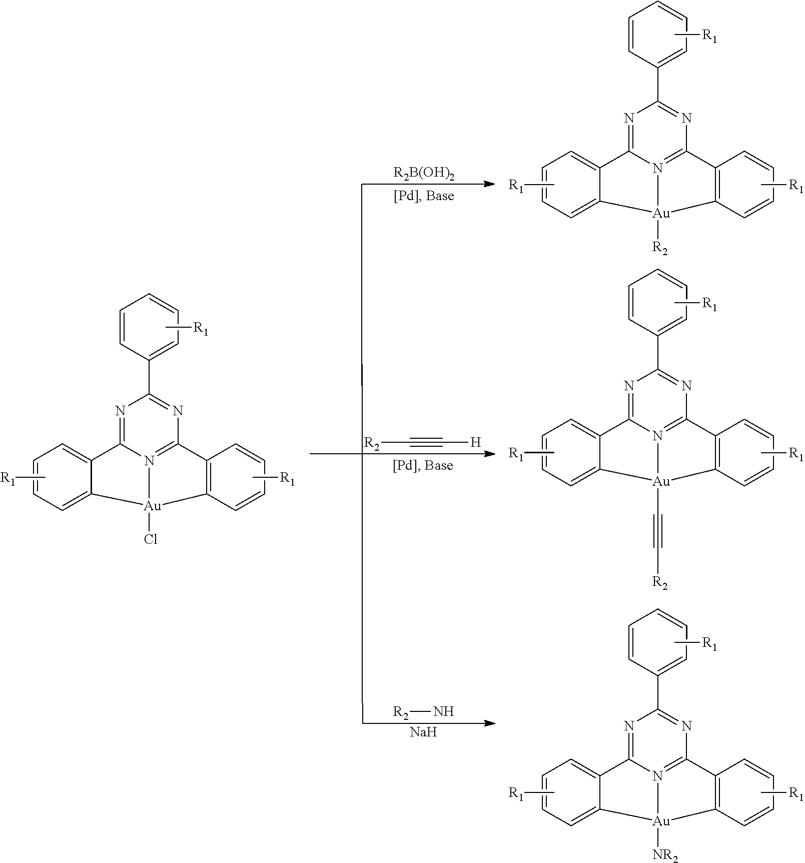
wherein:
(d) R₁ is selected from, but are not limited to, alkyl, alkenyl, alkynyl, alkylaryl, aryl and cycloalkyl with one or more alkyl, alkenyl, alkynyl, alkylaryl, cycloalkyl, OR, NR₂, SR, C(O)R, C(O)OR, C(O)NR₂, CN, CF₃, NO₂, SO₂, SOR, SO₃R, halo, aryl, substituted aryl, heteroaryl, substituted heteroaryl or a heterocyclic group, wherein R is independently alkyl, alkenyl, alkynyl, alkylaryl, aryl or cycloalkyl. R₁ could also be heteroatom and is selected from, but not limited to, boron, carbon, silicon, nitrogen, phosphorus, oxygen, sulphur, selenium, fluorine, chlorine, bromine, or iodine;
(e) R₂ is selected from, but is not limited to, alkyl, substituted alkyl, aryl, substituted aryl, heteroaryl, substituted heteroaryl, heterocyclic, substituted heterocyclic, alkenyl, substituted alkenyl, alkynyl or substituted alkynyl, wherein the heteroaryl or heterocyclic group could have heteroatom selected from, but not limited to, boron, carbon, silicon, nitrogen, phosphorus, oxygen, sulphur, selenium, fluorine, chlorine, bromine, or iodine; and
(f) n is zero, a positive integer or a negative integer.
